(19) United States
(12) Patent Application Publication
(10) Pub. No.: US 2025/0385117 A1
(43) Pub. Date: Dec. 18, 2025

(54) ELECTROSTATIC CHUCK AND PLASMA PROCESSING APPARATUS INCLUDING THE SAME

(71) Applicant: SAMSUNG ELECTRONICS CO., LTD., Suwon-si (KR)

(72) Inventors: Jongwha LEE, Suwon-si (KR); Dong-Jin Lim, Suwon-si (KR); Hyoil Chio, Suwon-si (KR); Dea Woong Han, Suwon-si (KR)

(73) Assignee: SAMSUNG ELECTRONICS CO., LTD., Suwon-si (KR)

(21) Appl. No.: 18/970,502

(22) Filed: Dec. 5, 2024

(30) Foreign Application Priority Data
Jun. 14, 2024 (KR) 10-2024-0077651

(51) Int. Cl. H01L 21/683; H01J 37/32

(52) U.S. Cl. CPC H01L 21/6833; H01J 37/32715; H01J 2237/2007

(57) ABSTRACT

Provided is an electrostatic chuck and a plasma processing apparatus including same, the electrostatic chuck including: an upper plate including an upper surface, the upper surface including a center region configured to have a substrate mounted thereto and an edge region surrounding the center region; a lower plate under the upper plate and supporting the upper plate; and a focus ring on the edge region, wherein the center region and the edge region are on the same plane, and wherein a thickness of the upper plate in the center region is the same as a thickness of the upper plate in the edge region.

### CROSS-REFERENCE TO RELATED APPLICATION

This application is based on and claims priority to Korean Patent Application No. 10-2024-0077651, filed in the Korean Intellectual Property Office on Jun. 14, 2024, the entire contents of which are hereby incorporated by reference.

### BACKGROUND

### 1. Field

The present disclosure relates to an electrostatic chuck and a plasma processing apparatus including the same.

### 2. Description of Related Art

An electrostatic chuck is a device used to secure a substrate (wafer) in place during semiconductor manufacturing processes. The electrostatic chuck firmly secures the substrate using electrostatic force, thereby preventing the substrate from moving or wobbling during processing. The electrostatic chuck may be used in processes such as plasma processing, etching, deposition, etc.

The design of the electrostatic chuck can directly affect the plasma uniformity. For example, the surface pattern, material, electrode arrangement, etc. of the electrostatic chuck may affect the plasma density distribution. As semiconductor processes become more refined, uniformity of plasma density is becoming increasingly important since tiny defects or non-uniformities can significantly impact the performance of semiconductor devices.

Therefore, to ensure high quality and consistency in the semiconductor manufacturing process, various efforts are being made to improve the uniformity of plasma density during plasma processing.

### SUMMARY

Provided is an electrostatic chuck configured to enhance the uniformity of plasma density.

Also provided is a plasma processing apparatus including an electrostatic chuck configured to enhance the uniformity of plasma density.

According to an aspect of the disclosure, an electrostatic chuck includes: an upper plate including an upper surface, the upper surface including a center region configured to have a substrate mounted thereto and an edge region surrounding the center region; a lower plate under the upper plate and supporting the upper plate; and a focus ring on the edge region, wherein the center region and the edge region are on the same plane, and wherein a thickness of the upper plate in the center region is the same as a thickness of the upper plate in the edge region.

According to an aspect of the disclosure, an electrostatic chuck includes: an upper plate including an upper surface, the upper surface including a center region configured to have a substrate mounted thereto and an edge region surrounding the center region; a lower plate under the upper plate and supporting the upper plate; a focus ring on the edge region; a heater in the upper plate; a substrate adhesion electrode in the upper plate; a cooling channel in the lower plate, wherein the cooling channel is configured to allow coolant to flow therethrough; and a plurality of gas flow paths formed through each of the upper plate and the lower plate in a vertical direction, wherein the edge region vertically overlaps at least one of the heater, the substrate adhesion electrode, the cooling channel, and at least one gas flow path of the plurality of gas flow paths.

According to an aspect of the disclosure, a plasma processing apparatus includes: a chamber including a plasma processing space; a source supply on a ceiling surface of the chamber, wherein the source supply is configured to supply a plasma source gas to the plasma processing space; an electrostatic chuck in a lower inner portion of the chamber; and a base under the electrostatic chuck and supporting the electrostatic chuck, wherein the electrostatic chuck includes: an upper plate including an upper surface, the upper surface including a center region configured to have a substrate mounted thereto and an edge region surrounding the center region; a lower plate under the upper plate and supporting the upper plate; and a focus ring on the edge region, wherein the center region and the edge region are on the same plane, and wherein a thickness of the upper plate in the center region is the same as a thickness of the upper plate in the edge region.

### BRIEF DESCRIPTION OF DRAWINGS

The above and other aspects and features of certain embodiments of the present disclosure will be more apparent from the following description taken in conjunction with the accompanying drawings, in which:

FIG. 1 is a diagram provided to explain a plasma processing apparatus according to one or more embodiments of the present disclosure;

FIG. 2 is a cross-sectional view of an electrostatic chuck according to one or more embodiments of the present disclosure;

FIG. 3 is an elevation view of an electrostatic chuck according to one or more embodiments of the present disclosure;

FIG. 4 is an elevation view of an electrostatic chuck according to one or more embodiments of the present disclosure;

FIG. 5 is a plan view of a heater according to one or more embodiments of the present disclosure;

FIG. 6 is a plan view of a cooling channel according to one or more embodiments of the present disclosure;

FIG. 7 is a plan view of a substrate adhesion electrode according to one or more embodiments of the present disclosure;

FIG. 8 is a plan view of a substrate adhesion electrode according to one or more embodiments of the present disclosure;

FIG. 9 is a plan view of a gas flow path according to one or more embodiments of the present disclosure;

FIG. 10 is a plan view of a gas flow path according to one or more embodiments of the present disclosure;

FIG. 11 is an enlarged view of region R of FIG. 2;

FIG. 12 is an enlarged view of region R of FIG. 2;

FIG. 13 is a diagram illustrating an incident angle of plasma radicals and ions with respect to an electrostatic chuck in a comparative example; and

FIG. 14 is a diagram illustrating an incident angle of plasma radicals and ions with respect to an electrostatic chuck according to one or more embodiments of the present disclosure.

### DETAILED DESCRIPTION

Hereinafter, an electrostatic chuck and a plasma processing apparatus including the electrostatic chuck will be described in detail with reference to the accompanying drawings. In the following drawings, the same reference numerals refer to the same or like components, and the size of each component in the drawings may be exaggerated for clarity and convenience of explanation. In addition, the example embodiments described below are merely illustrative, and various modifications are possible from these example embodiments.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

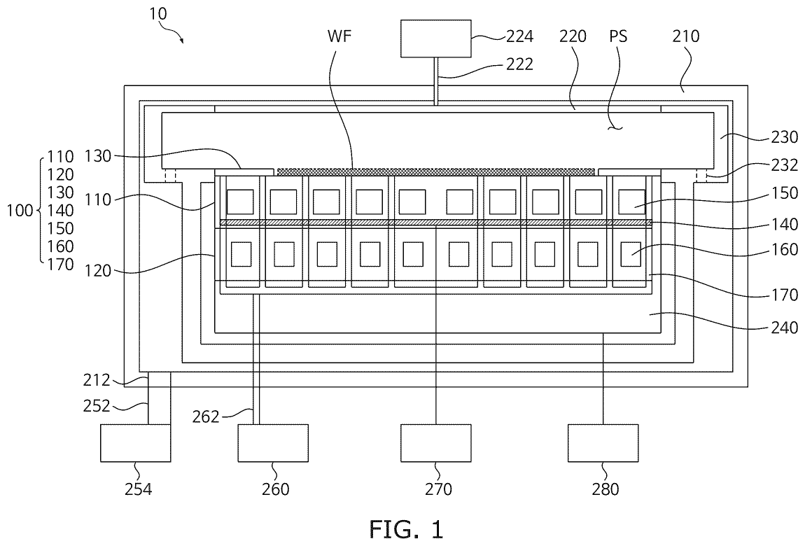

FIG. 1 is a diagram provided to explain a plasma processing apparatus 10. The plasma processing apparatus 10 may be an apparatus that performs a process of processing a substrate WF using plasma to manufacture a semiconductor device. For example, the plasma processing apparatus 10 may be a capacitively coupled plasma apparatus, an inductively coupled plasma apparatus, or a microwave plasma apparatus. The plasma processing apparatus 10 may be an etching apparatus or a deposition apparatus. The substrate WF may be a semiconductor substrate for forming micropatterns for a semiconductor device. For example, the substrate WF may be a semiconductor substrate including silicon or germanium. As another example, the substrate WF may be a silicon-on-insulator (SOI) substrate. In another example, the substrate WF may be a glass substrate for forming micropatterns for a flat panel display device.

Referring to FIG. 1, the plasma processing apparatus 10 may include a chamber 210 including a plasma processing space PS, a source supply 220 disposed on a ceiling surface of the chamber 210 and supplying a plasma source gas to the plasma processing space PS, an electrostatic chuck 100 disposed in a lower portion of the chamber 210 and adhere to or otherwise fixing the substrate WF, and a base 240 disposed under the electrostatic chuck 100 and supporting the electrostatic chuck 100.

The chamber 210 may provide a space independent and sealed from the outside. The chamber 210 may be configured to be openable and closable. For example, the chamber 210 may include an opening/closing part to introduce or remove the substrate WF. The plasma processing apparatus 10 may include a loading unit to mount or load the substrate WF introduced into the chamber onto the electrostatic chuck 100. The electrostatic chuck 100 may be configured to be ascendable or descendable. The plasma processing apparatus 10 may include a cylinder assembly for lifting or lowering the electrostatic chuck 100 and the base 240. As another example, the base 240 may include a cylinder assembly for lifting or lowering the electrostatic chuck 100.

The chamber 210 may include the plasma processing space PS. For example, the chamber 210 may include the plasma processing space PS defined by the source supply 220 disposed on the ceiling surface of the chamber 210, the electrostatic chuck 100 spaced downward from the source supply 220, and a sealing cover 230 connecting both sides of the source supply 220 and the electrostatic chuck 100, respectively.

The chamber 210 may include an outlet 212 for discharging the gas used during plasma processing to the outside. The gas used during plasma processing may be discharged from the plasma processing space PS through a gas discharge passage 232 disposed on one side of the sealing cover 230. The gas discharged from the plasma processing space PS may be discharged to a plasma gas discharge unit 254 disposed outside the chamber 210 through an intake 252 connected to the outlet 212. The plasma gas discharge unit 254 may include a vacuum pump. The plasma gas discharge unit 254 may provide a vacuum pressure to remove the gas used during plasma processing.

The source supply 220 may be disposed on the ceiling surface of the chamber 210. The source supply 220 may be spaced apart from and above the electrostatic chuck 100. The source supply 220 may supply the plasma source gas to the plasma processing space PS. The source supply 220 may include an upper electrode to generate plasma. The source supply 220 may include a plurality of electrodes. For example, the source supply 220 may include an internal electrode and an external electrode surrounding the internal electrode, but the disclosure is not limited thereto.

The source supply 220 may be connected to a gas source 224 through a gas supply line 222. The gas source 224 may be disposed outside the chamber 210. The gas supply line 222 may supply plasma source gas provided from the gas source 224 into the chamber 210. Although FIG. 1 illustrates that the gas supply line 222 and the gas source 224 are disposed above the chamber 210, the disclosure is not limited thereto. The positions of the gas supply line 222 and the gas source 224 may vary depending on the design of the plasma processing apparatus. In addition, although FIG. 1 illustrates that plasma source gas is provided from the gas source 224 through the gas supply line 222, the disclosure is not limited thereto, and the gas source 224 may be attached directly to the chamber 210.

The electrostatic chuck 100 may be disposed in a lower inner portion of the chamber 210. The electrostatic chuck 100 may include an upper plate 110, a lower plate 120 disposed under the upper plate 110 and supporting the upper plate 110, and a ring-shaped focus ring 130 disposed above the upper plate 110.

A substrate WF on which plasma processing is to be performed may be chucked onto an upper surface 112 of the upper plate 110. For example, the substrate WF may be chucked onto a center region CA by an electrostatic voltage applied to a substrate adhesion electrode 140 disposed in the upper plate 110.

The upper plate 110 may be a dielectric. For example, the upper plate 110 may include a ceramic (e.g., aluminum oxide layer (Al₂O₃), aluminum nitride layer (AlN), yttrium oxide layer (Y₂O₃)), or resin (e.g., polyimide). The upper plate 110 may have a circular shape (e.g., a cylindrical shape) or a disk shape.

The lower plate 120 may include a metallic material. For example, the lower plate 120 may include a metallic material such as aluminum (Al), titanium (Ti), stainless steel, tungsten (W), or alloys thereof. The lower plate may have a circular shape (e.g., a cylindrical shape) or a disk shape.

The focus ring 130 may be disposed above the upper plate 110. The focus ring 130 may have a ring shape. The focus ring 130 may be disposed to surround the substrate WF seated on the upper surface of the upper plate 110. The focus ring 130 may include the same material as the substrate WF. For example, the focus ring 130 may include silicon or germanium, which is the same material as the substrate WF. In another example, the focus ring 130 may include the same material as a silicon-on-insulator (SOI) substrate.

A heater 150 may be disposed in the upper plate 110. For example, the heater 150 may be disposed in the upper plate 110 and a voltage to emit heat may be applied thereto. The heater 150 may be disposed above the substrate adhesion electrode 140. The heater 150 may be a conductor. For example, the heater 150 may include a metallic material such as tungsten (W), copper (Cu), nickel (Ni), molybdenum (Mo), titanium (Ti), nickel-chromium (Ni—Cr) alloy, nickel-aluminum (Ni—Al) alloy, etc., or a conductive ceramic such as tungsten carbide (WC), molybdenum carbide (MoC), titanium nitride (TiN), etc.

The heater 150 may have various patterns such as a circular or spiral pattern, or a combination thereof. For example, the heater 150 may include at least one or more concentric circular heaters 150 centered around the central axis of the upper plate 110. In another example, the heater 150 may include at least one or more spiral heaters 150 centered around the central axis of the upper plate 110.

The heater 150 may be electrically connected to a heater power source. The heater 150 may be configured to be heated by a voltage (e.g., an AC voltage) supplied from the heater power source to adjust the temperature of the electrostatic chuck 100.

The substrate adhesion electrode 140 may be disposed in the upper plate 110. For example, the substrate adhesion electrode 140 may be disposed in the upper plate 110 and a voltage to fix or adhere to the substrate WF may be applied thereto. The substrate adhesion electrode 140 may be disposed above a cooling channel 160. The substrate adhesion electrode 140 may be referred to as a clamp electrode. The substrate adhesion electrode 140 may include a metallic material such as tungsten (W), copper (Cu), nickel (Ni), molybdenum (Mo), titanium (Ti), nickel-chromium (Ni—Cr) alloy, nickel-aluminum (Ni—Al) alloy, etc., or a conductive ceramic such as tungsten carbide (WC), molybdenum carbide (MoC), titanium nitride (TiN), etc. In some example embodiments, the substrate adhesion electrode 140 may be disposed in the lower plate 120.

The substrate adhesion electrode 140 may be electrically connected to an electrostatic chuck power source 270. The substrate adhesion electrode 140 may be configured to generate an electrostatic force between the substrate adhesion electrode 140 and the substrate WF by a voltage (e.g., a DC voltage) supplied from the electrostatic chuck power source 270 to fix or adhere to the substrate WF on the upper plate 110.

The substrate adhesion electrode 140 may be a unipolar electrode or a bipolar electrode. The substrate adhesion electrode 140 may have various patterns including a combination of a circular pattern and a cyclic pattern, a circular pattern, a combination of two semicircular patterns, etc. For example, the unipolar substrate adhesion electrode 140 may include a circular substrate adhesion electrode 140 centered around the central axis of the upper plate 110. In contrast, the bipolar substrate adhesion electrode 140 may include a plurality of concentric circular substrate adhesion electrodes 140 having different sizes centered around the central axis of the upper plate 110. The substrate adhesion electrode 140 may include at least one groove to avoid interference with other components disposed in the electrostatic chuck 100.

The cooling channel 160 through which a coolant may flow may be disposed in the lower plate 120. For example, the coolant may be a cooling water and may include water, ethylene glycol, silicone oil, liquid Teflon, and a mixture of water and glycol. However, the disclosure is not limited thereto.

The cooling channel 160 may have various patterns including a circular, spiral, or a combination thereof. For example, the cooling channel 160 may include at least one concentric cooling channel 160 centered around the central axis of the lower plate 120. In another example, the cooling channel 160 may include at least one spiral cooling channel 160 centered around the central axis of the lower plate 120. The cooling channel 160 may include an inlet through which the coolant flows in and an outlet through which the coolant flows out.

A gas flow path 170 may be disposed in the upper plate 110 and the lower plate 120. For example, a plurality of gas flow paths 170 formed through each of the upper plate 110 and the lower plate 120 in the vertical direction may be included in the upper plate 110 and the lower plate 120. The plurality of gas flow paths 170 may extend up to the upper surface of the upper plate 110 and may be exposed on the upper surface of the upper plate 110 in the shape of a plurality of holes spaced apart from each other. The cooling gas may flow through the plurality of gas flow paths 170. The cooling gas may include helium (He), but the disclosure is not limited thereto.

The plurality of gas flow paths 170 may be connected to a cooling gas supply 260 through a cooling gas supply line 262. The cooling gas supply 260 may be disposed outside the chamber 210. The plurality of gas flow paths 170 may supply cooling gas toward lower surfaces of the substrate and the focus ring 130. The substrate WF and the focus ring 130 heated during plasma processing may be cooled by the cooling gas.

The base 240 may be disposed under the electrostatic chuck 100. For example, the base 240 may be disposed on a lower surface of the chamber 210 to support the electrostatic chuck 100. The base 240 may be electrically connected to a bias power source 280. High frequency or radio frequency from the bias power source 280 may be applied to the base 240. The electrostatic chuck 100 may serve as a lower electrode for plasma generation due to the high frequency power applied through the base 240.

The base 240 may further include an additional component for operating the plasma processing apparatus 10. For example, the base 240 may include a temperature sensor for measuring the temperature of at least one of the electrostatic chuck 100, the substrate WF, and the interior of the plasma processing apparatus 10. The additional component included in the base 240 is not limited to the example described above and may vary depending on the design of the plasma processing apparatus 10. In addition, the plasma processing apparatus 10 may further include a control unit for controlling each component of the plasma processing apparatus 10. The control unit may be electrically connected to the cooling gas supply 260, the heater power source, the electrostatic chuck power source 270, the bias power source 280, valves installed on the gas supply line 222, temperature sensors, flow rate sensors, etc. to control each component.

FIG. 1 illustrates an example in which the heater 150, the substrate adhesion electrode 140, and the cooling channel 160 are sequentially arranged from top to bottom, but the disclosure is not limited thereto and they may be arranged in various orders. In addition, FIG. 1 illustrates an example in which the heater 150 and the substrate adhesion electrode 140 are disposed in the upper plate 110 and the cooling channel 160 is disposed in the lower plate 120, but the disclosure is not limited thereto.

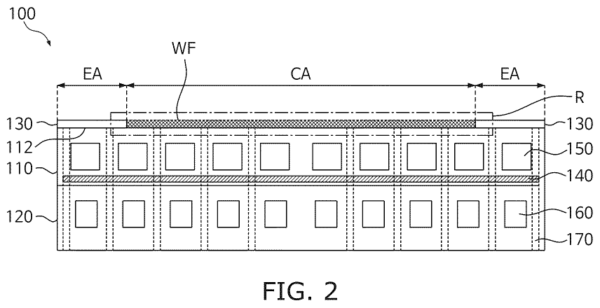

FIG. 2 is a cross-sectional view of the electrostatic chuck 100. The components in the electrostatic chuck 100 already described above with reference to FIG. 1 will not be redundantly described below.

Referring to FIG. 2, the electrostatic chuck 100 may include the upper plate 110 including the upper surface 112 having the center region CA on which the substrate WF is mounted, and an edge region EA that surrounds the center region CA in a ring shape. The lower plate 120 disposed under the upper plate 110 to support the upper plate 110, and the ring-shaped focus ring 130 disposed on the edge region EA. The center region CA may refer to the region that corresponds in size to the substrate WF (e.g., the diameter of the substrate WF) or the region that corresponds to an inner diameter of the focus ring 130 surrounding the substrate WF. In addition, the edge region EA may refer to the region that corresponds to the planar shape of the focus ring 130.

The center region CA and the edge region EA may be disposed on the same plane. For example, the center region CA and the edge region EA may be disposed on the same plane (e.g., on the upper surface 112 of the upper plate 110 in a cylindrical shape) with no steps formed therebetween, respectively. The center region CA and the edge region EA may have the same or corresponding vertical level.

FIG. 2 illustrates an example in which the edge region EA vertically overlaps all of the heater 150, the substrate adhesion electrode 140, the cooling channel 160, and the plurality of gas flow paths 170, but the disclosure is not limited thereto. In one or more example embodiments, the edge region EA may vertically overlap at least one of the heater 150, the substrate adhesion electrode 140, the cooling channel 160, and one or more of the plurality of gas flow paths 170.

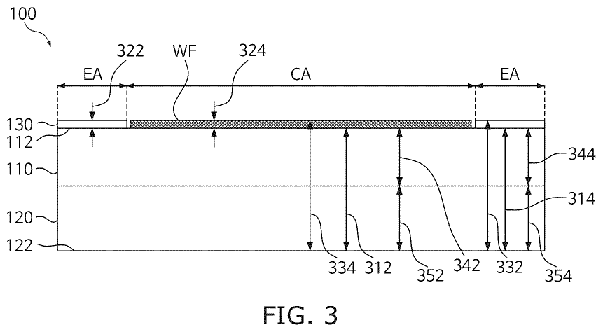

FIG. 3 is an elevation view of the electrostatic chuck 100. The electrostatic chuck 100 may have a constant height in the center region CA and the edge region EA. For example, a distance 312 from the lower surface 122 of the lower plate 120 to the upper surface 112 of the upper plate 110 in the center region CA may be the same as a distance 314 from the lower surface 122 of the lower plate 120 to the upper surface 112 of the upper plate 110 in the edge region EA.

Additionally or alternatively, a thickness 322 of the focus ring 130 may be the same as a thickness 324 of the substrate WF. In other words, with the substrate WF mounted on the center region CA, the distance from the upper surface 112 of the upper plate 110 to the upper surface of the substrate WF may be the same as the distance from the upper surface 112 of the upper plate 110 to the upper surface of the focus ring 130. For example, the thickness 322 of the focus ring 130 and the thickness of the substrate WF may be about 75 mm, but the disclosure is not limited thereto.

Additionally or alternatively, with the substrate WF mounted on the center region CA, a distance 332 from the lower surface 122 of the lower plate 120 to the upper surface of the focus ring 130 in the center region CA may be the same as a distance 334 from the lower surface 122 of the lower plate 120 to the upper surface of the substrate WF in the edge region EA.

The upper plate 110 may have a constant height in the center region CA and the edge region EA. For example, a thickness 342 of the upper plate 110 in the center region CA may be the same as a thickness 344 of the upper plate 110 in the edge region EA.

The lower plate 120 may have a constant height in a region corresponding to the center region CA and the edge region EA. For example, a thickness 352 of the lower plate 120 in a region corresponding to the center region CA may be the same as a thickness 354 of the lower plate 120 in a region corresponding to the edge region EA.

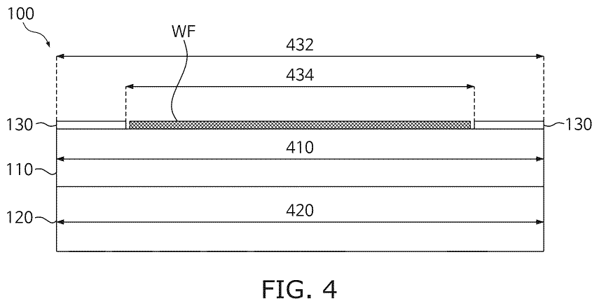

FIG. 4 is an elevation view of the electrostatic chuck 100.

The electrostatic chuck 100 may have a constant diameter at all heights (e.g., at all vertical levels). For example, the upper plate 110 may have a cylindrical shape, and may have a constant diameter (e.g., a diameter 410 of the upper plate 110) from the upper surface of the upper plate 110 to the lower surface of the upper plate 110. In addition, the lower plate 120 may have a cylindrical shape, and may have a constant diameter (e.g., a diameter 420 of the lower plate 120) from the upper surface of the lower plate 120 to the lower surface of the lower plate 120.

The diameter 410 of the upper plate 110 may be greater than the inner diameter 434 of the focus ring 130. In addition, the diameter 410 of the upper plate 110 may be greater than the diameter of the substrate WF. For example, if the diameter of the substrate WF is about 300 mm, the diameter 410 of the upper plate 110 may be 308 mm to 312 mm, but the disclosure is not limited thereto.

The diameter 410 of the upper plate 110 may be the same as an outer diameter 432 of the focus ring. In addition, the diameter 410 of the upper plate 110, the diameter 420 of the lower plate 120, and the outer diameter 432 of the focus ring 130 may be the same.

The upper plate 110 and the focus ring 130 may not overlap in a horizontal direction. Additionally, each of the upper plate 110, the lower plate 120, and the focus ring 130 may be disposed parallel to the ground (i.e., the base of plasma processing apparatus 10) and may not overlap in the horizontal direction.

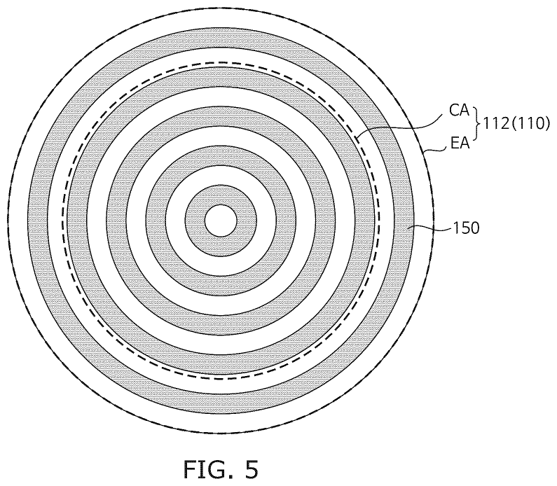

FIG. 5 is a plan view of the heater 150. FIG. 5 may be a plan view of the upper plate 110 illustrated in FIGS. 1 and 2, taken parallel to the base of plasma processing apparatus 10.

Referring to FIG. 5, the heater 150 may include at least one concentric heater 150 centered around the central axis of the upper plate 110. The heater 150 may be disposed in a region in the upper plate 110 that corresponds to the center region CA and the edge region EA. For example, the heater 150 may vertically overlap each of the center region CA and the edge region EA. The outline of the region where the heater 150 is disposed may vertically overlap the edge region EA.

The shape of the heater 150 in FIG. 5 is illustrated for the convenience of description, and the heater 150 may be designed in various shapes.

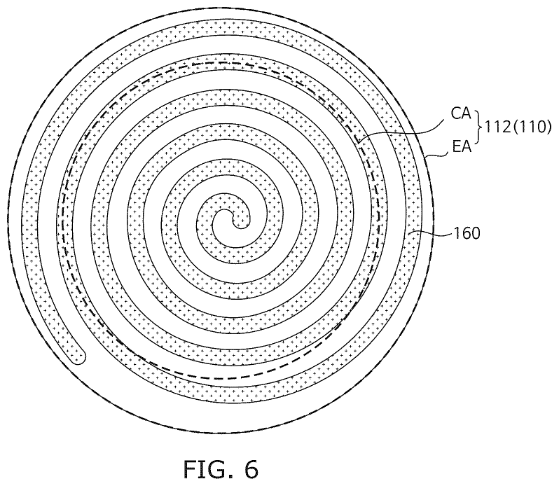

FIG. 6 is a plan view of the cooling channel 160. FIG. 6 may be a plan view of the lower plate 120 shown in FIGS. 1 and 2, taken parallel to the base of plasma processing apparatus 10.

Referring to FIG. 6, the cooling channel 160 may include at least one spiral cooling channel 160 centered around the central axis of the lower plate 120. The cooling channel 160 may be disposed in a region in the lower plate (e.g., 120 in FIG. 1) that corresponds to the center region CA and the edge region EA. For example, the cooling channel 160 may vertically overlap each of the center region CA and the edge region EA. The outline of the region where the cooling channel 160 is disposed may vertically overlap the edge region EA.

The shape of the cooling channel 160 in FIG. 6 is illustrated for the convenience of description, and the cooling channel 160 may be designed in various shapes.

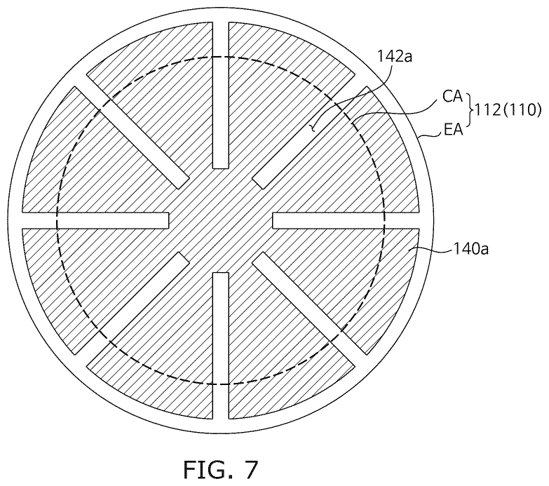

FIG. 7 is a plan view of a substrate adhesion electrode 140a. FIG. 7 is a plan view of the upper plate 110 shown in FIGS. 1 and 2, taken parallel to the base of plasma processing apparatus 10.

The substrate adhesion electrode 140a may be a unipolar electrode. The substrate adhesion electrode 140a may include at least one groove 142a to avoid interference with other components disposed in the electrostatic chuck 100.

Referring to FIG. 7, the substrate adhesion electrode 140a may be disposed in a region in the upper plate 110 that corresponds to the center region CA and the edge region EA. For example, the substrate adhesion electrode 140a may vertically overlap each of the center region CA and the edge region EA. The outline of the region where the substrate adhesion electrode 140a is disposed may vertically overlap the edge region EA.

The shape of the substrate adhesion electrode 140a in FIG. 7 is illustrated for the convenience of description, and the substrate adhesion electrode 140a may be designed in various shapes.

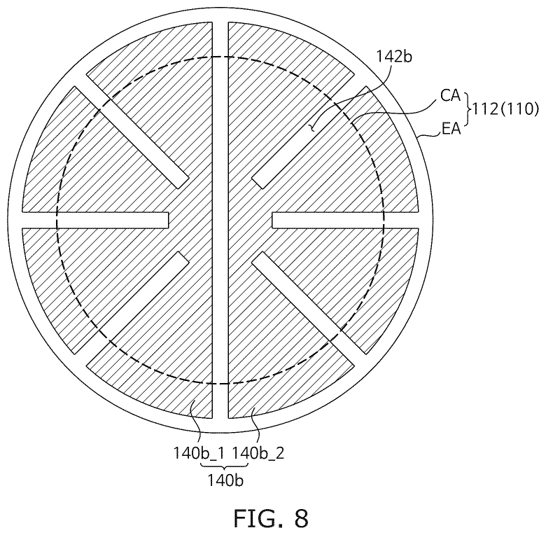

FIG. 8 is a plan view of a substrate adhesion electrode 140b. FIG. 8 may be a plan view of the upper plate 110 shown in FIGS. 1 and 2, taken parallel to the base of plasma processing apparatus 10.

The substrate adhesion electrode 140b may be a bipolar electrode. For example, as shown, the substrate adhesion electrode 140b may include a first electrode 140b_1 and a second electrode 140b_2 having a different polarity from the first electrode 140b_1. The substrate adhesion electrode 140b may include at least one groove 142b to avoid interference with other components disposed in the electrostatic chuck 100.

Referring to FIG. 8, the substrate adhesion electrode 140b may be disposed in a region in the upper plate 110 that corresponds to the center region CA and the edge region EA. For example, the substrate adhesion electrode 140b may vertically overlap each of the center region CA and the edge region EA. The outline of the region where the substrate adhesion electrode 140b is disposed may vertically overlap the edge region EA. In another example, the outline of the region where one of the first electrode 140b_1 and the second electrode 140b_2 of the substrate adhesion electrode 140b is disposed may vertically overlap the edge region EA. In this case, the other electrode may vertically overlap only the center region CA without vertically overlapping the edge region EA.

The shape of the substrate adhesion electrode 140b in FIG. 8 is illustrated for the convenience of description, and the substrate adhesion electrode 140b may be designed in various shapes. FIG. 8 illustrates the bipolar electrode including two electrodes 140b_1 and 140b_2, but the disclosure is not limited thereto. The substrate adhesion electrode 140b, which is the bipolar electrode, may include three or more electrodes.

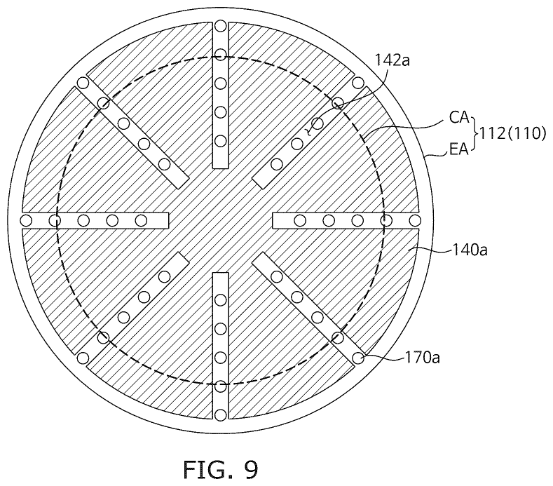

FIG. 9 is a plan view of a gas flow path 170a. FIG. 9 may be a plan view of the upper plate 110 shown in FIGS. 1 and 2, taken parallel to the base of plasma processing apparatus 10. In addition, the substrate adhesion electrode 140a illustrated in FIG. 9 may represent the substrate adhesion electrode 140a which is the unipolar electrode illustrated in FIG. 7.

The gas flow path 170a may be disposed in the at least one groove 142a formed in the substrate adhesion electrode 140a to avoid interference with the substrate adhesion electrode 140a.

Referring to FIG. 9, the gas flow path 170a may be disposed in a region in the upper plate 110 and the lower plate 120 that corresponds to the center region CA and the edge region EA. For example, the gas flow path 170a may vertically overlap each of the center region CA and the edge region EA. The outline of the region where the gas flow path 170a is disposed may vertically overlap the edge region EA.

The position of gas flow path 170a in FIG. 9 is illustrated for the convenience of description, and the gas flow path 170a may be disposed at various positions depending on the design.

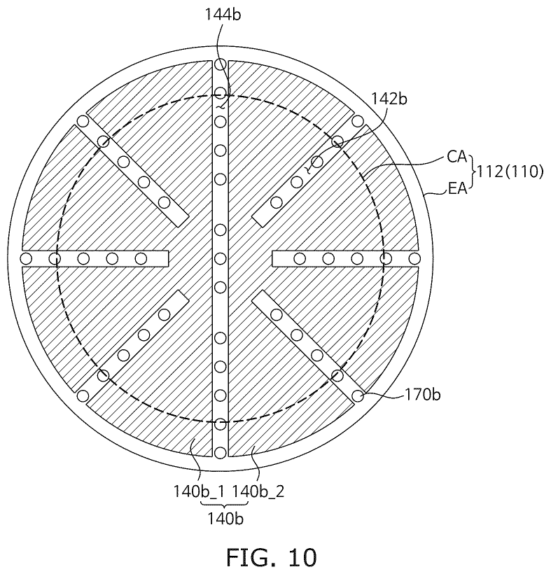

FIG. 10 is a plan view of a gas flow path 170b. FIG. 10 is a plan view of the upper plate 110 shown in FIGS. 1 and 2, taken parallel to the base of plasma processing apparatus 10. In addition, the substrate adhesion electrode 140b illustrated in FIG. 10 may represent the substrate adhesion electrode 140b which is the bipolar electrode illustrated in FIG. 8.

The gas flow path 170b may be disposed in the at least one groove 142b formed in the substrate adhesion electrode 140b, and in a separating space 144b formed between the first electrode 140b_1 and the second electrode 140b_2 to avoid interference with the substrate adhesion electrode 140b.

Referring to FIG. 10, the gas flow path 170b may be disposed in a region in the upper plate 110 and the lower plate 120 that corresponds to the center region CA and the edge region EA. For example, the gas flow path 170b may vertically overlap each of the center region CA and the edge region EA. The outline of the region where the gas flow path 170b is disposed may vertically overlap the edge region EA.

The position of the gas flow path 170b in FIG. 10 is illustrated for the convenience of description, and the gas flow path 170b may be disposed at various positions depending on the design.

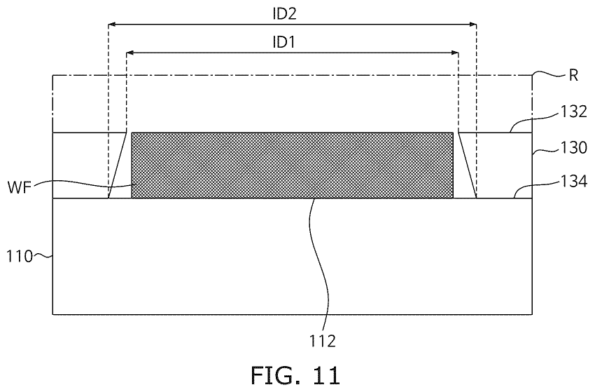

FIG. 11 is an enlarged view of region R of FIG. 2.

The focus ring 130 may include an upper surface 132 and a lower surface 134 opposing the upper surface 132 and facing the upper surface 112 of the upper plate 110, in which an inner diameter ID1 of the upper surface 132 of the focus ring 130 may be smaller than an inner diameter ID2 of the lower surface 134 of the focus ring 130.

With the substrate WF mounted, a distance between the upper surface 132 of the focus ring 130 and the substrate WF may be less than a distance between the lower surface 134 of the focus ring 130 and the substrate WF.

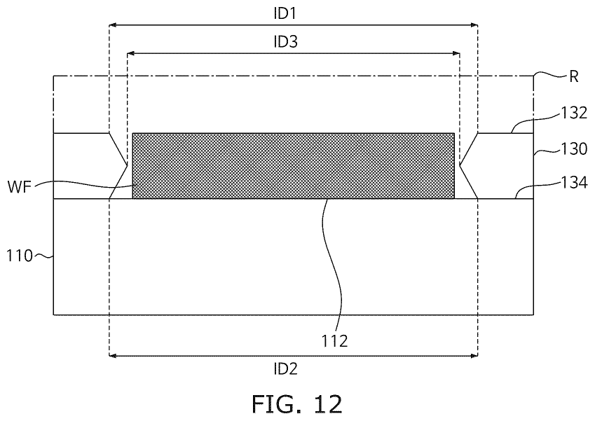

FIG. 12 is an enlarged view of the region R of FIG. 2.

The focus ring 130 may include the upper surface 132 and the lower surface 134 opposing the upper surface 132 and facing the upper surface 112 of the upper plate 110, in which an inner diameter ID3 of the focus ring 130 between the upper surface 132 and the lower surface 134 may be smaller than the inner diameter ID1 of the upper surface 132 of the focus ring 130 and the inner diameter ID2 of the lower surface 134 of the focus ring 130.

With the substrate WF mounted, a distance from a portion of the focus ring 130 between the upper and lower surfaces 132 and 134 to the substrate WF may be less than a distance between the upper surface 132 and the substrate WF and a distance between the lower surface 134 and the substrate WF.

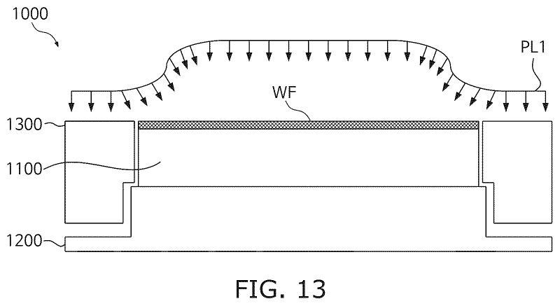

FIG. 13 is a diagram illustrating an incident angle PL1 of plasma radicals and ions with respect to an electrostatic chuck 1000 in a comparative example.

The electrostatic chuck 1000 in the comparative example may include an upper plate 1100 having a size (e.g., diameter) corresponding to the substrate WF, a focus ring 1300 disposed on a side of the upper plate 1100 and surrounding the upper plate 1100 and the substrate WF, and a lower plate 1200 having a stepped structure on which the focus ring 1300 is disposed.

In this case, the incident angle PL1 of radicals and ions may tilt due to the height of the focus ring 1300, changes over time in the inner and outer diameters of the focus ring 1300, different vertical cross-sectional structures in the inner and outer regions of the electrostatic chuck 1000, etc. Accordingly, there is an issue with the profile of holes, formed during the etching process of semiconductor devices, being tilted, causing a decrease in the yield of semiconductor devices.

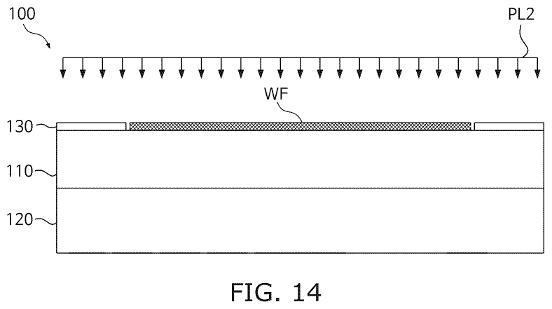

FIG. 14 is a view illustrating an incident angle PL2 of plasma radicals and ions with respect to the electrostatic chuck 100 of the present disclosure.

The electrostatic chuck 100 may include the upper plate 110 including the upper surface having the center region on which the substrate is mounted and an edge region surrounding the center region in a ring shape, the lower plate 120 disposed under the upper plate 110 and supporting the upper plate 110, and the ring-shaped focus ring 130 disposed on the edge region. In this case, the upper surface of the upper plate 110 may be generally formed on the same plane. Accordingly, the electrostatic chuck 1000 may have the same vertical cross-sectional structure in both the inner region (e.g., center region) and the outer region (e.g., edge region) so that the uniformity of the incident angle PL2 of the radicals and ions, that is, the uniformity of the plasma density may improve.

Although the present disclosure has been described above by way of certain aspects and drawings, the present disclosure is not limited thereto, and it goes without saying that various changes and modifications can be made within the equivalent scope of the technical idea of the present disclosure and the claims to be described below by those of ordinary skill in the art.

What is claimed is:

1. An electrostatic chuck comprising:
an upper plate comprising an upper surface, the upper surface comprising a center region configured to have a substrate mounted thereto and an edge region surrounding the center region;
a lower plate under the upper plate and supporting the upper plate; and
a focus ring on the edge region,
wherein the center region and the edge region are on the same plane, and
wherein a thickness of the upper plate in the center region is the same as a thickness of the upper plate in the edge region.

2. The electrostatic chuck of claim 1, wherein a distance from a lower surface of the lower plate to the upper surface of the upper plate in the center region is the same as a distance from a lower surface of the lower plate to the upper surface of the upper plate in the edge region.

3. The electrostatic chuck of claim 1, wherein, with the substrate mounted on the center region, a distance from the upper surface of the upper plate to an upper surface of the substrate is the same as a distance from the upper surface of the upper plate to an upper surface of the focus ring.

4. The electrostatic chuck of claim 1,
wherein the upper plate comprises a cylindrical shape, and
wherein a diameter of the upper plate is constant from the upper surface of the upper plate to a lower surface of the upper plate.

5. The electrostatic chuck of claim 1, wherein the upper plate and the focus ring do not overlap in a horizontal direction.

6. The electrostatic chuck of claim 1, wherein a diameter of the upper plate, a diameter of the lower plate, and an outer diameter of the focus ring are the same.

7. The electrostatic chuck of claim 1, further comprising a substrate adhesion electrode,
wherein the substrate adhesion electrode is in the upper plate or in the lower plate, and
wherein the substrate adhesion electrode vertically overlaps each of the center region and the edge region.

8. The electrostatic chuck of claim 1, further comprising at least one heater in the upper plate,
wherein the at least one heater vertically overlaps each of the center region and the edge region.

9. The electrostatic chuck of claim 1, further comprising a cooling channel in the lower plate,
wherein the cooling channel vertically overlaps each of the center region and the edge region.

10. The electrostatic chuck of claim 1, further comprising a plurality of gas flow paths formed through each of the upper plate and the lower plate in a direction perpendicular to the upper surface of the upper plate,
wherein the plurality of gas flow paths vertically overlaps the center region and the edge region.

11. The electrostatic chuck of claim 1, further comprising:
a cooling channel configured to allow a coolant to flow therethrough;
a substrate adhesion electrode above the cooling channel; and
at least one heater above the substrate adhesion electrode,
wherein application of a first voltage to the substrate adhesion electrode causes the substrate to adhere to the substrate adhesion electrode, and
wherein application of a second voltage to the at least one heater causes the at least one heater to emit heat.

12. The electrostatic chuck of claim 1, wherein the focus ring comprises a same material as the substrate.

13. The electrostatic chuck of claim 1,
wherein the focus ring comprises an upper surface and a lower surface opposing the upper surface,
wherein the lower surface of the focus ring faces the upper surface of the upper plate, and
wherein an inner diameter of the upper surface of the focus ring is smaller than an inner diameter of a lower surface of the focus ring.

14. The electrostatic chuck of claim 1,
wherein the focus ring comprises an upper surface and a lower surface opposing the upper surface,
wherein the lower surface of the focus ring faces the upper surface of the upper plate, and
wherein an inner diameter of the focus ring between the upper and the lower surfaces of the focus ring is smaller than an inner diameter of the upper surface of the focus ring and an inner diameter of the lower surface of the focus ring.

15. An electrostatic chuck comprising:
an upper plate comprising an upper surface, the upper surface comprising a center region configured to have a substrate mounted thereto and an edge region surrounding the center region;
a lower plate under the upper plate and supporting the upper plate;
a focus ring on the edge region;
a heater in the upper plate;
a substrate adhesion electrode in the upper plate;
a cooling channel in the lower plate, wherein the cooling channel is configured to allow coolant to flow therethrough; and
a plurality of gas flow paths formed through each of the upper plate and the lower plate in a vertical direction,
wherein the edge region vertically overlaps at least one of the heater, the substrate adhesion electrode, the cooling channel, and at least one gas flow path of the plurality of gas flow paths.

16. The electrostatic chuck of claim 15, wherein a thickness of the focus ring is the same as a thickness of the substrate.

17. The electrostatic chuck of claim 15, wherein a diameter of the upper plate and an outer diameter of the focus ring are the same.

18. The electrostatic chuck of claim 15, wherein the diameter of the upper plate is larger than an inner diameter of the focus ring.

19. The electrostatic chuck of claim 15, wherein each of the upper plate, the lower plate, and the focus ring is parallel to a base of the electrostatic chuck and does not overlap in a horizontal direction.

20. A plasma processing apparatus comprising:
a chamber comprising a plasma processing space;
a source supply on a ceiling surface of the chamber, wherein the source supply is configured to supply a plasma source gas to the plasma processing space;
an electrostatic chuck in a lower inner portion of the chamber; and
a base under the electrostatic chuck and supporting the electrostatic chuck,
wherein the electrostatic chuck comprises:
an upper plate comprising an upper surface, the upper surface comprising a center region configured to have a substrate mounted thereto and an edge region surrounding the center region;
a lower plate under the upper plate and supporting the upper plate; and
a focus ring on the edge region,
wherein the center region and the edge region are on the same plane, and
wherein a thickness of the upper plate in the center region is the same as a thickness of the upper plate in the edge region.
